(19) United States
(12) Patent Application Publication
(10) Pub. No.: US 2020/0144397 A1
(43) Pub. Date: May 7, 2020

(54) METHODS AND APPARATUS FOR SILICON-GERMANIUM PRE-CLEAN

(71) Applicant: Applied Materials, Inc., Santa Clara, CA (US)

(72) Inventors: Abhishek DUBE, Fremont, CA (US); Sheng-Chin KUNG, Milpitas, CA (US); Malcolm BEVAN, Santa Clara, CA (US); Johanes SWENBERG, Los Gatos, CA (US)

(73) Assignees: Applied Materials, Inc., Santa Clara, CA (US); Applied Materials, Inc., Santa Clara, CA (US)

(21) Appl. No.: 16/572,886

(22) Filed: Sep. 17, 2019

Related U.S. Application Data
(60) Provisional application No. 62/755,736, filed on Nov. 5, 2018.

(51) Int. Cl. H01L 29/66; H01L 29/417; H01L 29/78; H01L 21/8234; H01L 21/02; H01L 21/67

(52) U.S. Cl. CPC H01L 29/66795; H01L 29/41791; H01L 29/785; H01L 21/02532; H01L 21/02041; H01L 21/67028; H01L 21/823431

(57) ABSTRACT

Methods and apparatuses for processing substrates, such as during silicon-germanium pre-cleans, are provided. A method includes introducing the substrate into a processing system, where the substrate contains a plurality of silicon-containing (e.g., SiGe) fins and a contaminant disposed on the silicon-containing fins, and exposing the substrate to a plasma treatment to remove at least a portion of the contaminant disposed from the silicon-containing fins. The method also includes exposing the substrate to an oxidation treatment to produce an oxide layer on the silicon-containing fins and the remaining contaminant thereon, then exposing the substrate to a dry-clean treatment to remove the oxide layer and the remaining contaminant from the silicon-containing fins and produce a cleaned surface thereon, and depositing an epitaxial layer on the cleaned surface on the silicon-containing fins.

### CROSS-REFERENCE TO RELATED APPLICATIONS

This application claims benefit to U.S. Appl. No. 62/755,736, filed on Nov. 5, 2018, which is herein incorporated by reference.

### BACKGROUND

### Field

Embodiments generally related to substrate processing, and more specifically relate to clean and deposition processes.

### Description of the Related Art

As circuit densities increase for next generation devices, the widths of interconnects, such as vias, trenches, contacts, gate structures and other features, as well as the dielectric materials therebetween, decrease to smaller dimensions, whereas the thickness of the dielectric layers remain substantially constant, with the result of increasing the aspect ratios of the features. Recently, complementary metal oxide semiconductor (CMOS) Fin field-effect transistor (FinFET) devices have been widely used in many logic and other applications and are integrated into various different types of semiconductor devices.

The FinFET devices typically include semiconductor fins with high aspect ratios in which the channel and source/drain regions for the transistor are formed thereover. A gate electrode is then formed over and alongside of a portion of the fin devices utilizing the advantage of the increased surface area of the channel and source/drain regions to produce faster, more reliable and better-controlled semiconductor transistor devices. Further advantages of FinFETs include reducing the short channel effect and providing higher current flow.

Current pre-clean processes for silicon-germanium include wet-clean techniques which are not very favorable, especially on FinFET devices. The wet-clean techniques generally increase the Q-time before applying an epi deposition process. Also, silicon-germanium materials and structures are typically sensitive to the wet-clean solutions and techniques and can easily be damaged while being exposed to and manipulated in a wet bath.

Thus, there is a need for improved methods for pre-cleaning silicon-germanium materials and structures.

### SUMMARY OF THE INVENTION

In one or more embodiments, a method of processing a substrate includes introducing the substrate into a processing system, where the substrate contains a plurality of silicon-containing fins and a contaminant disposed on the silicon-containing fins, and exposing the substrate to a plasma treatment to remove at least a portion of the contaminant disposed from the silicon-containing fins. The method also includes exposing the substrate to an oxidation treatment to produce an oxide layer on the silicon-containing fins and the remaining contaminant thereon, then exposing the substrate to a dry-clean treatment to remove the oxide layer and the remaining contaminant from the silicon-containing fins and produce a cleaned surface thereon, and depositing an epitaxial layer on the cleaned surface on the silicon-containing fins.

In other embodiments, a method of processing a substrate includes introducing the substrate into a processing system, where the substrate contains a plurality of silicon-containing fins and a contaminant disposed on the silicon-containing fins, and the processing system contains first, second, third, and fourth processing chambers coupled to a mainframe. The method also includes exposing the substrate to a plasma treatment to remove at least a portion of the contaminant disposed from the silicon-containing fins within the first processing chamber, transferring the substrate from the first processing chamber to the second processing chamber, and exposing the substrate to an oxidation treatment to produce an oxide layer on the silicon-containing fins and the remaining contaminant thereon within the second processing chamber. The method further includes transferring the substrate from the second processing chamber to the third processing chamber, exposing the substrate to a dry-clean treatment to remove the oxide layer and the remaining contaminant from the silicon-containing fins and produce a cleaned surface thereon within the third processing chamber, transferring the substrate from the third processing chamber to the fourth processing chamber, and depositing an epitaxial layer on the cleaned surface on the silicon-containing fins within the fourth processing chamber.

In other embodiments, a cluster tool for processing a substrate includes a transfer chamber coupled to a load-lock chamber, a first cleaning chamber coupled to the transfer chamber, the first cleaning chamber containing an inductively coupled plasma source, and the first cleaning chamber is in fluid communication with a source of hydrogen, and an oxidation chamber coupled to the transfer chamber, the oxidation chamber containing a plasma source and is in fluid communication with a source of oxygen. The cluster tool also includes a second cleaning chamber coupled to the transfer chamber, the second cleaning chamber containing a capacitively coupled plasma source and a substrate support coupling to a bias RF power supply, and the second cleaning chamber is in fluid communication with a source of a fluorine-containing compound (e.g., NF₃), and an epitaxy chamber coupled to the transfer chamber, the epitaxy chamber containing a liquid precursor vaporizer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a flow chart illustrating a method of processing a substrate with a plurality of silicon-containing (e.g., SiGe) fins, as described and discussed in one or more embodiments herein.

FIGS. 2A-2E depicts cross-sectional views of a substrate during various stages of fabrication, as described and discussed in one or more embodiments herein.

FIG. 3 depicts a schematic top view of a processing system that can be used to complete the method illustrated in the flow chart of FIG. 1, as described and discussed in one or more embodiments herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described and discussed herein provide methods for processing a substrate that includes introducing the substrate into a processing system, where the substrate contains a plurality of silicon-containing (e.g., SiGe) fins and one or more contaminants (e.g., oxides, carbon, particulates, and/or other materials) disposed on the silicon-containing fins. The method includes exposing the substrate to a plasma treatment to remove at least a portion of the contaminant disposed from the silicon-containing fins, and then exposing the substrate to an oxidation treatment to produce an oxide layer on the silicon-containing fins and the remaining contaminant thereon. The method also includes exposing the substrate to a dry-clean treatment to remove the oxide layer and the remaining contaminant from the silicon-containing fins and produce a cleaned surface thereon, and depositing an epitaxial layer on the cleaned surface on the silicon-containing fins.

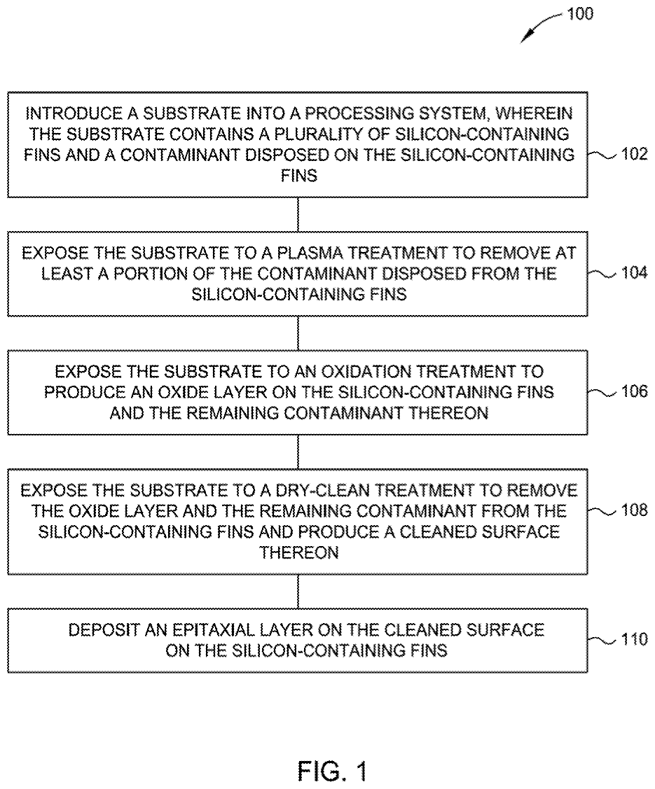

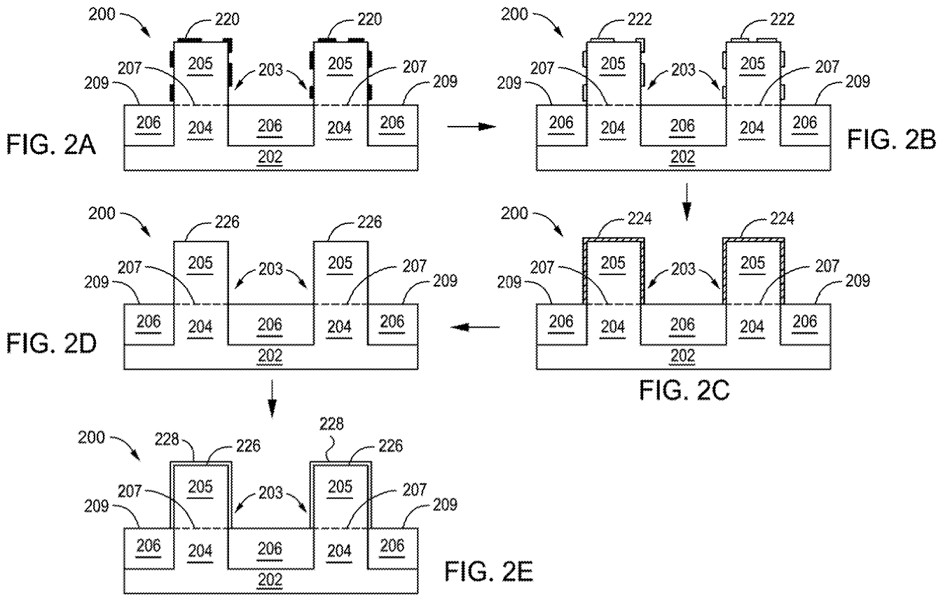

FIG. 1 is a flow chart illustrating a method 100 for processing a substrate with a plurality of silicon-containing fins. In one or more examples, the silicon-containing fins can be or contain silicon-germanium. The silicon-containing fins can be utilized as a portion of a Fin field-effect transistor (FinFET) or other MOSFET transistors produced on the substrate. FIGS. 2A-2E illustrate cross-sectional views of a simplified substrate or semiconductor structure 200 during certain stages of fabrication according to the flow chart of FIG. 1. Those skilled in the art will further recognize that the full process for forming a semiconductor device and the associated structures are not illustrated in the drawings or described herein. Instead, for simplicity and clarity, only so much of a process for forming a semiconductor device and the associated structures as is unique to the present disclosure or necessary for an understanding of the present disclosure is depicted and described. In addition, although various operations are illustrated in the drawings and described herein, no limitation regarding the order of such operations or the presence or absence of intervening operations is implied. Operations depicted or described as sequential are, unless explicitly specified, merely done so for purposes of explanation without precluding the possibility that the respective operations are actually performed in concurrent or overlapping manner, at least partially if not entirely.

The process 100 begins at block 102 in FIG. 1 by loading, placing or otherwise introducing a substrate or semiconductor structure 200 into a processing system containing a plurality of processing chambers. The substrate or semiconductor structure 200 contains an underlying substrate or wafer 202, a plurality of semiconductor or silicon-containing fins 203 (only two are shown), and a dielectric material 206 disposed between the silicon-containing fins 203 on the underlying substrate or wafer 202, as shown in FIG. 2A.

The terms “substrate” and “wafer” as used herein are intended to broadly cover any object that can be processed in a process chamber. For example, the underlying substrate or wafer 202 may be any substrate capable of having material deposited thereon, such as a silicon substrate, for example silicon (doped or undoped), crystalline silicon (e.g., Si <100> or Si <111>), silicon oxide, strained silicon, doped or undoped polysilicon, or the like, germanium, a III-V compound substrate, a silicon germanium (SiGe) substrate, a silicon germanium carbide (SiGeC) substrate, a silicon germanium oxide (SiGeO) substrate, a silicon germanium oxynitride (SiGeON) substrate, a silicon carbide (SiC) substrate, a silicon carbonitride (SiCN) substrate, a silicon carbonoxide (SiCO), an epi substrate, a silicon-on-insulator (SOI) substrate, a carbon doped oxide, a silicon nitride, a display substrate such as a liquid crystal display (LCD), a plasma display, an electro luminescence (EL) lamp display, a solar array, solar panel, a light emitting diode (LED) substrate, a patterned or non-patterned semiconductor wafer, glass, sapphire, or any other materials such as metals, metal alloys, and other conductive materials. The underlying substrate or wafer 202 may be a planar substrate or a patterned substrate. Patterned substrates are substrates that include electronic features formed into or onto a processing surface of the substrate. The underlying substrate or wafer 202 may include multiple layers, or include, for example, partially fabricated devices such as transistors, flash memory devices, and the like.

In one or more examples, the underlying substrate or wafer 202 is a monocrystalline silicon-germanium (SiGe) wafer. In other examples, the underlying substrate or wafer 202 is a monocrystalline silicon wafer, such as a P-doped silicon wafer. The silicon-containing fins 203 may include the same or different material as the underlying substrate or wafer 202. In the implementation as shown, the silicon-containing fins 203 and the underlying substrate or wafer 202 are formed of the same material. In one or more embodiment, the silicon-containing fins 203 contain a silicon-germanium (SiGe) material. The dielectric material 206 may form isolation regions, such as shallow trench isolation (STI) regions, and may include silicon oxide, silicon nitride, silicon carbonitride, or any suitable dielectric material.

The silicon-containing fins 203 may be employed in forming channels for FinFET transistor in later stages. Each of the silicon-containing fins 203 may include a first portion 204 which has a surface 207 that is coplanar with a surface 209 of the dielectric material 206, and a second portion 205 that protrudes upwardly from the first portion 204. The second portion 205 may be functioned as a source or drain region. Therefore, a top surface of the substrate or semiconductor structure 200 includes one or more semiconductor regions, e.g., the first portion 204 and/or the second portion 205 of the silicon-containing fins 203, and one or more dielectric regions, e.g., the dielectric material 206.

As depicted in FIG. 2A, contaminant 220 is disposed on one or more surfaces of the substrate or semiconductor structure 200, specifically disposed on the silicon-containing fins 203. The contaminant 220 can be or include native oxides, carbon, carbon-containing compounds, organic compounds, siloxanes, mask remnants, or any combination thereof.

In one or more embodiments, the process 100 is used to remove the contaminant 220 from the silicon-containing fins 203 prior to depositing or otherwise forming an epitaxial stressor film (not illustrated in FIGS. 2A-2E). In other embodiments, not depicted, the process 100 can be used to remove the contaminant from an epitaxial stressor film grown, deposited, or otherwise formed over the silicon-containing fins 203.

At block 104 in FIG. 1, the substrate 200 is exposed to a plasma treatment to remove at least a portion of the contaminant 220 disposed from the silicon-containing fins 203. The plasma treatment includes exposing the substrate 200 to a hydrogen plasma within a plasma processing chamber. The hydrogen plasma removes at least some, not the majority of any carbon contained in the contaminant 220 during the plasma treatment to leave behind remaining contaminant 222, as depicted in FIG. 2B.

In some configurations, the hydrogen plasma cleaning process may be performed in a processing chamber using a remote plasma source. For example, the processing chamber may be an AKTIV Pre-Clean® chamber, commercially available from Applied Materials, Inc. of Santa Clara, Calif. In other examples, the hydrogen plasma cleaning process may be performed in an etch chamber using an inductively coupled plasma (ICP) source.

The substrate 200 and the contaminant 220 can be exposed to the hydrogen plasma for a period of less than 20 minutes or less than 15 minutes, such as about 0.1 seconds, about 0.5 seconds, about 1 second, about 10 seconds, about 30 seconds, or about 60 seconds to about 1.5 minutes, about 2 minutes, about 3 minutes, about 4 minutes, about 5 minutes, about 7 minutes, or about 10 minutes. For example, the substrate 200 and the contaminant 220 can be exposed to the hydrogen plasma for a period of about 0.1 seconds to about 10 minutes, about 0.1 seconds to about 8 minutes, about 0.1 seconds to about 5 minutes, or about 0.1 seconds to about 3 minutes. In one or more examples, the substrate 200 and the contaminant 220 is exposed to the hydrogen plasma for less than 5 minutes. During the hydrogen plasma process, the plasma processing chamber may be have an inner pressure of about 10 mTorr to about 300 Torr, such as about 10 mTorr to about 500 mTorr or about 20 Torr to about 300 Torr.

At block 106 in FIG. 1, the substrate 200 and the remaining contaminant 222 can be exposed to an oxidation treatment to produce an oxide layer 224 on the silicon-containing fins 203 and the remaining contaminant 222 on the silicon-containing fins 203, as depicted in FIG. 2C. The oxidation treatment includes exposing the substrate 200 to one or more oxidizing agents and to plasma, ions, radicals, or a combination thereof. The oxidizing agent can be or include one or more of oxygen plasma, oxygen, ozone, atomic oxygen, water, plasmas thereof, ions thereof, radicals thereof, or any combination thereof. The oxide layer 224 can be conformal or non-conformal and can have a thickness of about 1 Å, about 2 Å, about 5 Å, about 8 Å, about 10 Å, or about 12 Å to about 15 Å, about 18 Å, about 20 Å, about 25 Å, about 30 Å, about 40 Å, or about 50 Å. For example, the oxide layer 224 can have a thickness of about 1 Å to about 50 Å, about 5 Å to about 30 Å, about 5 Å to about 25 Å, about 5 Å to about 20 Å, about 5 Å to about 15 Å, about 5 Å to about 10 Å, about 10 Å to about 50 Å, about 10 Å to about 30 Å, about 10 Å to about 25 Å, about 10 Å to about 20 Å, or about 10 Å to about 15 Å.

In one or more embodiments, the oxidation treatment includes exposing the substrate 200 and the remaining contaminant 222 to an oxygen plasma generated by a remote plasma source (RPS) or an in situ plasma chamber. For example, the oxidation treatment can be or include one or more types of plasma processes, such as ae decoupled plasma oxidation (DPO), a remote plasma oxidation (RPO), and/or a plasma pre-cleaning process containing one or more oxidizing agents. In other examples, the processing chamber 310 is a thermal processing chamber. In one or more embodiments, the processing chamber 310 is a VANTAGE® RADOX™ RTP chamber available from Applied Materials, Inc. of Santa Clara, Calif.

The temperature of the substrate 200 and/or the processing chamber can be maintained at a fairly low process temperature during the oxidation treatment. The process temperature can be about 25° C., about 50° C., about 80° C., about 100° C., or about 150° C. to about 200° C., about 250° C., about 300° C., about 400° C., or about 500° C. during the oxidation treatment. For example, the process temperature can be about 25° C. to about 500° C., about 25° C. to about 400° C., about 25° C. to about 350° C., about 25° C. to about 300° C., about 25° C. to about 250° C., about 25° C. to about 200° C., or about 25° C. to about 100° C. during the oxidation treatment.

The substrate 200 and the remaining contaminant 222 can be exposed to the oxygen plasma for a period of less than 20 minutes or less than 15 minutes, such as about 0.1 seconds, about 0.5 seconds, about 1 second, about 10 seconds, about 30 seconds, or about 60 seconds to about 1.5 minutes, about 2 minutes, about 3 minutes, about 4 minutes, about 5 minutes, about 7 minutes, or about 10 minutes. For example, the substrate 200 and the contaminant 220 can be exposed to the oxygen plasma for a period of about 0.1 seconds to about 10 minutes, about 0.1 seconds to about 8 minutes, about 0.1 seconds to about 5 minutes, or about 0.1 seconds to about 3 minutes. In one or more examples, the substrate 200 and the contaminant 220 is exposed to the oxygen plasma for less than 5 minutes. During the oxidation treatment process, the plasma processing chamber may be have an inner pressure of about 10 mTorr to about 300 Torr, such as about 10 mTorr to about 500 mTorr or about 20 Torr to about 300 Torr.

At block 108 in FIG. 1, the substrate 200 is exposed to a dry-clean treatment to remove the oxide layer 224 and the remaining contaminant 222 from the silicon-containing fins 203 to produce a cleaned surface 226 on the silicon-containing fins 203, as depicted in FIG. 2D. Any suitable dry-clean treatment process that removes oxides from the substrate without significantly damaging the substrate may be used. Suitable dry-clean treatment processes include sputter etch processes, plasma-based oxide etch processes, or combinations thereof. The dry-clean treatment can include exposing the substrate 200 to an etchant and to plasma, ions, radicals, or a combination thereof. The etchant can be or include one or more fluorine, chlorine, nitrogen, plasmas thereof, ions thereof, radicals thereof, or any combination thereof. The dry-clean treatment includes exposing the substrate 200 to a fluorine plasma generated from a combination of nitrogen trifluoride (NF₃) and ammonia (NH₃). Exemplary plasma-based oxide etch processes include NF₃/NH₃ inductively coupled plasma processes or NF₃/NH₃ capacitively coupled plasma processes.

In one implementation, the dry-clean treatment is a plasma-based oxide etch process that is a remote plasma assisted dry etch process which involves the simultaneous exposure of a substrate to NF₃ and NH₃ plasma by-products. In one example, the plasma-based oxide etch process may be similar to or may include a SiCoNi® etch process that is commercially available from Applied Materials, Inc. of Santa Clara, Calif. The SiCoNi® etch process may be performed in a SiCoNi® Preclean chamber, commercially available from Applied Materials, Inc. of Santa Clara, Calif.

In some examples that use remote plasma, excitation of the gas species allows plasma-damage-free substrate processing. The remote plasma etch can be largely conformal and selective towards silicon oxide layers, and thus does not readily etch silicon regardless of whether the silicon is amorphous, crystalline or polycrystalline. The remote plasma process will generally produce solid by-products which grow on the surface of the substrate as substrate material is removed. The solid by-products can be subsequently removed via sublimation when the temperature of the substrate is raised (e.g., 300° C.). The plasma etch process results in the removal of oxides and a substrate surface having silicon-hydrogen (Si—H) bonds thereon.

In some examples, the dry-clean treatment process may be performed in a processing chamber using an RPS. For example, the processing chamber may be an AKTIV Pre-Clean® chamber, commercially available from Applied Materials, Inc. of Santa Clara, Calif. In other examples, the dry-clean treatment process may be performed in an etch chamber using an ICP source. For example, the etch chamber may be a Centura® Advantedge® Mesa® Etch chamber, commercially available from Applied Materials, Inc. of Santa Clara, Calif. Alternatively, the cleaning process may be performed in an etch chamber employing a radical-based chemistry.

The substrate 200 is exposed to the etchant during the dry-clean treatment to remove the oxide layer 224 and the remaining contaminant 222 for a period of about 20 minutes or less. The substrate 200 can be exposed to the etchant for a period of about 10 seconds, about 20 seconds, about 30 seconds, about 45 seconds, about 1 minute, about 1.5 minutes, or about 2 minutes to about 3 minutes, about 5 minutes, about 7 minutes, about 10 minutes, about 12 minutes, about 15 minutes, or about 20 minutes.

At block 110 in FIG. 1, an epitaxial layer 228 is deposited, grown, or otherwise formed on the cleaned surface 226 on the silicon-containing fins 203. The process 100 can be application to the substrate 200 prior to various different types of fabrication applications. The epitaxial layer 228 can be a capping layer, stressor growth layer, or other types of layers. For example, the process 100 can be applied to the substrate 200 prior to depositing a silicon capping layer used in gate oxide applications. In other examples, the process 100 can be applied to the substrate 200 prior to depositing a stressor growth layer used in source-drain applications. In one or more examples, the epitaxial layer 228 is or includes an epi-silicon layer.

In one or more embodiments, the substrate 200 and the cleaned surface 226 are exposed to a processing reagent in, for example, a gas phase epitaxy chamber at a target temperature for epitaxial deposition of a silicon-containing layer. An exemplary epitaxy chamber that may be used is a Centura® RP EPI chamber available from Applied Materials, Inc. of Santa Clara, Calif. The target temperature for epitaxial deposition may be between about 250° C. and about 600° C., such as about 300° C. to about 500° C., for example about 350° C. to about 400° C. The pressure within the epitaxy chamber is kept relatively low, for example, less than about 50 Torr, such as about 0.1 Torr to about 45 Torr, about 1 Torr to about 45 Torr, or about 10 Torr to about 40 Torr.

In some examples, the processing reagent may include one or more deposition gases and at least one dopant gas. The deposition gas may include one or more precursor gases selected from Group III precursor gas, Group IV precursor gas, Group V precursor gas, or Group VI precursor gas. In cases where a silicon-containing epitaxial layer is formed, the deposition gas may contain at least a silicon source. Exemplary silicon sources may include, but are not limited to, silanes, halogenated silanes, silicon tetrachloride (SiCl₄), or any combinations thereof. Silanes may include silane (SiH₄) and higher silanes with the empirical formula SiₓH₍₂ₓ₊₂₎, such as disilane (Si₂H₆), trisilane (Si₃H₅), tetrasilane (Si₄H₁₀), pentasilane (Si₅H₁₂), or hexasilane (Si₆H₁₄). Other higher silanes, such as a silicon hydride expressed as SiₙH₂ₙ (n is a natural number equal to or greater than 3), may also be used. For example, cyclotrisilane (Si₃H₆), cyclotetrasilane (Si₄H₅), cyclopentasilane (Si₆H₁₀), cyclohexasilane (Si₆H₁₂), or cycloheptasilane (Si₇H₁₄). Halogenated silanes may include monochlorosilane (MCS), dichlorosilane (DCS), trichlorosilane (TCS), hexachlorodisilane (HODS), octachlorotrisilane (OCTS), silicon tetrachloride (STC), or a combination thereof. In some examples, silanes may include higher order silanes with varying degrees of halogenation in the form of F, Cl, Br, or I attached to them in order to enable selectivity. For example, the silane can be or include Si₂H₄Cl₂ or Si₃H₅Cl₃.

The dopant gas can be or include, but is not limited to phosphorous, boron, arsenic, gallium, or aluminum, depending on the desired conductive characteristic of the deposited epitaxial layer. The deposition gas may optionally contain at least one secondary elemental source, such as a germanium source or a carbon source. Depending on application, other elements, such as metals, halogens or hydrogen may be incorporated within a silicon-containing layer. In one or more examples, the silicon-containing epitaxial layer is phosphorous doped silicon (Si:P), which can be achieved using a dopant such as phosphine (PH₃), phosphorus trichloride (PCl₃), phosphorous tribromide (PBr₃), and phosphanes such as tributyl phosphate (TBP).

The processing reagents may optionally include a carrier gas. The carrier gas may be selected based on the precursor(s) used and/or the process temperature during the epitaxial process. Suitable carrier gases can be or include nitrogen, hydrogen, argon, helium, or other gases which are inert with respect to the epitaxial process. Nitrogen may be utilized as a carrier gas in examples featuring low temperature (e.g., <600° C.) processes. The carrier gas may have a flow rate from about 1 slm (standard liters per minute) to about 100 slm, such as from about 3 slm to about 30 slm.

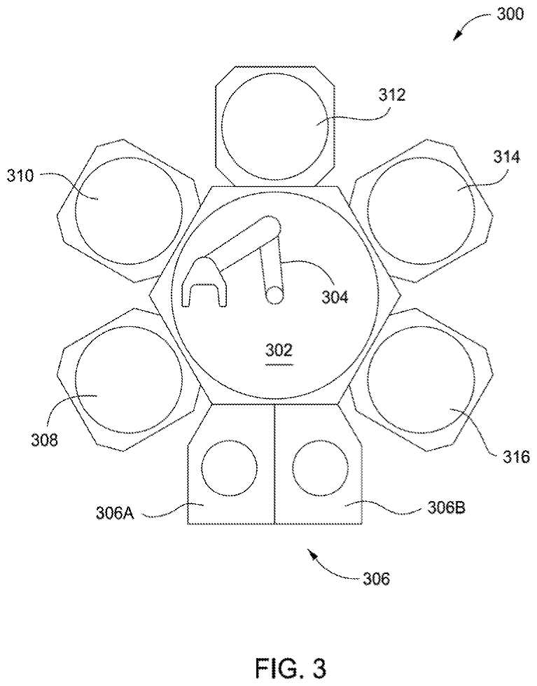

FIG. 3 is a schematic top view of a processing system 300 that can be used to complete the process 100 illustrated in FIG. 1 according to embodiments described herein. In some examples, the processing system 300 can be or include a cluster tool. One example of the processing system 300 is the CENTURA® system, commercially available from Applied Materials, Inc. of Santa Clara, Calif. A transfer robot 304 of any convenient type is disposed in a transfer chamber 302 of the processing system 300. A load-lock 306, with two load-lock chambers 306A, 306B is coupled to the transfer chamber 302. A plurality of processing chambers 308, 310, 312, 314, and 316 are also coupled to the transfer chamber 302. The plurality of processing chamber 308, 310, 312, 314, and 316 may include one or more of the chambers, such as a cleaning chamber, an oxidation chamber, an etching chamber, or an epitaxial chamber, as described in U.S. Pub. No. 2018/0230634.

The processing chamber 308 may also be a cleaning chamber configured to clean a substrate prior to deposition. For example, the processing chamber 308 may be a pre-clean chamber using remote plasma source. In one or more embodiments, the processing chamber 308 is an AKTIV Pre-Clean™ chamber available from Applied Materials, Inc. of Santa Clara, Calif. The processing chamber 308 uses electrically neutral radicals (e.g., hydrogen radicals) to react with and clean oxides and/or contaminants on a substrate as discussed above in block 104.

The processing chamber 310 may be an oxidation or thermal processing chamber configured to provide a controlled oxidation and/or thermal cycle that heats a substrate. In one or more examples, the processing chamber 310 is an oxidation processing chamber. The processing chamber 310 can have a RPS for generating an oxidizing plasma. In other examples, the processing chamber 310 is a thermal processing chamber. In one or more embodiments, the processing chamber 310 is a VANTAGE® RADOX™ RTP chamber available from Applied Materials, Inc. of Santa Clara, Calif. The processing chamber 310 may be used to perform downstream processing after deposition, such as thermal annealing, thermal cleaning, thermal chemical vapor deposition, thermal oxidation or thermal nitridation as discussed above in block 106.

The processing chamber 312 may be a cleaning chamber configured to clean a substrate prior to deposition. For example, the processing chamber 312 may be a capacitively coupled processing chamber. In one or more embodiments, the processing chamber 312 is a SICONI™ Preclean chamber, commercially available from Applied Materials, Inc. of Santa Clara, Calif. In other embodiments, the processing chamber 312 may be an etching chamber configured to etch material from a substrate. For example, the processing chamber 312 may be a plasma chamber such as an ICP plasma chamber. In one or more embodiments, the processing chamber 312 is a Centura® Advantedge™ Mesa™ Etch chamber available from Applied Materials, Inc. of Santa Clara, Calif. The processing chamber 312 may be used to perform the cleaning process as discussed above in block 108.

The processing chamber 314 may be a thermal processing chamber configured to deposit material on a substrate. For example, the processing chamber 314 may be a material deposition chamber such as an epitaxy chamber. In one or more embodiments, the processing chamber 314 is a Centura® RP EPI chamber, commercially available from Applied Materials, Inc. of Santa Clara, Calif. The processing chamber 314 may be used to perform an epitaxial growth process as discussed above in block 110.

The processing chamber 316 may be another chamber such as any one of the processing chambers 308, 310, 312, or 314. For example, the processing chamber 316 may be a cleaning chamber configured to clean a substrate (e.g., after deposition), a plasma chamber, a thermal processing chamber configured to provide a controlled thermal cycle that heats a substrate, a deposition chamber configured to deposit another material, or another type of processing chamber. In some embodiments, the processing chamber 316 may be absent or simply not used during an operation.

During processing, a substrate that is to be processed may arrive to the processing system 300 in a pod (not shown). The substrate is introduced into the processing system 300 at block 102 of process 100. The substrate is transferred from the pod to the vacuum compatible load-lock 306A, 306B by the factory interface robot (not shown). The substrate is then handled by the transfer robot 304 in the transfer chamber 302, which is generally kept in a vacuum state. The transfer robot 304 then loads the substrate into either processing chamber 308 or processing chamber 314 for cleaning of the substrate, as described in block 104. Upon completion of the cleaning, the transfer robot 304 then picks up the substrate from the processing chamber 308 or 314 and loads the substrate into the processing chamber 310 for an oxidation process, as described in block 104. The transfer robot 304 then picks up the substrate from the processing chamber 310 and loads the substrate into the processing chamber 312 for etching materials from the substrate, as described in block 108. The transfer robot 304 then picks up the substrate from the processing chamber 312 and loads the substrate into the processing chamber 314 for epitaxial growth of material (e.g., Si-epi) on the substrate and chamber purging, as described in block 110. This sequence is repeated until a predetermined thickness of the epitaxial film is reached.

Thereafter, the transfer robot 304 picks up the substrate from the processing chamber 314 and optional loads the substrate into the processing chamber 316 for any downstream processing, such as thermal annealing, thermal cleaning, thermal chemical vapor deposition, thermal oxidation or thermal nitridation, as discussed above. Alternatively, the transfer robot 304 move the substrate from the processing chamber 314 and loads the substrate into the load-lock 306B for removal from the processing system 300. During the process 100, all operations (blocks 104, 106, 108, and 110) are performed within the same processing system, therefore the substrate is not exposed to atmosphere (e.g., vacuum is not broken) as the substrate is transferred to various processing chambers, which decreases the chance of contamination and improves the quality of the deposited epitaxial film.

The transfer chamber 302 may remain under vacuum and/or at a pressure below atmosphere during the process. The vacuum level of the transfer chamber 302 may be adjusted to match the vacuum level of corresponding processing chambers. For example, when transferring a substrate from a transfer chamber 302 into a processing chamber (or vice versa), the transfer chamber 302 and the processing chamber may be maintained at the same vacuum level. Then, when transferring a substrate from the transfer chamber to the load lock chamber or batch load lock chamber (or vice versa), the transfer chamber vacuum level may match the vacuum level of the load-lock chamber 306A, 306B even through the vacuum level of the load-lock chamber and the processing chamber may be different.

In one or more embodiments, the processing system 300 (e.g., cluster tool) includes a transfer chamber 302 coupled to one or more load-lock chambers 306A, 306B and a first cleaning chamber 308 coupled to the transfer chamber 302. The first cleaning chamber 308 contains an inductively coupled plasma source and the first cleaning chamber 308 is in fluid communication with a source of hydrogen. The processing system 300 includes an oxidation chamber 310 is coupled to the transfer chamber 302. The oxidation chamber 310 contains a plasma source and is in fluid communication with a source of oxygen. The processing system 300 also includes a second cleaning chamber 312 coupled to the transfer chamber 302. The second cleaning chamber 312 contains a capacitively coupled plasma source and a substrate support coupling to a bias RF power supply. The second cleaning chamber 312 can be in fluid communication with a source of a fluorine-containing compound (e.g., NF₃). The processing system 300 also includes an epitaxy chamber 314 coupled to the transfer chamber 302. The epitaxy chamber 314 contains or is in fluid communication with a liquid precursor vaporizer (not shown). In some examples, the processing system 300 also includes another processing chamber 316 that can be or include a post deposition clean processing chamber or a thermal processing chamber coupled to the transfer chamber 302.

In one or more embodiments, the process 100 includes introducing the substrate into a first processing chamber for conducting the plasma treatment, exposing the substrate to the plasma treatment, transferring the substrate from the first processing chamber to a second processing chamber for conducting the oxidation treatment, and exposing the substrate to the oxidation treatment. The process 100 also includes transferring the substrate from the second processing chamber to a third processing chamber for conducting the dry-clean treatment, exposing the substrate to the dry-clean treatment, transferring the substrate from the third processing chamber to a fourth processing chamber for depositing the epitaxial layer, and depositing the epitaxial layer on the cleaned surface. The processing system contains the first, second, third, and fourth processing chambers coupled to a mainframe. The substrate is transferred between the first, second, third, and fourth processing chambers within a controlled environment maintained by the mainframe. The controlled environment has a lower pressure, a lower oxygen concentration, a lower water concentration, or a combination thereof than the ambient environment outside of the mainframe.

In other embodiments, the process 100 includes introducing the substrate into a processing system, where the substrate includes a plurality of silicon-containing fins and a contaminant disposed on the silicon-containing fins, and the processing system includes first, second, third, and fourth processing chambers coupled to a mainframe. The process 100 also includes exposing the substrate to a plasma treatment to remove at least a portion of the contaminant disposed from the silicon-containing fins within the first processing chamber, transferring the substrate from the first processing chamber to the second processing chamber, and exposing the substrate to an oxidation treatment to produce an oxide layer on the silicon-containing fins and the remaining contaminant thereon within the second processing chamber. The process 100 further includes transferring the substrate from the second processing chamber to the third processing chamber, exposing the substrate to a dry-clean treatment to remove the oxide layer and the remaining contaminant from the silicon-containing fins and produce a cleaned surface thereon within the third processing chamber, transferring the substrate from the third processing chamber to the fourth processing chamber, and depositing an epitaxial layer on the cleaned surface on the silicon-containing fins within the fourth processing chamber.

Embodiments of the present disclosure further relate to any one or more of the following paragraphs 1-28:

1. A method of processing a substrate, comprising: introducing the substrate into a processing system, wherein the substrate comprises a plurality of silicon-containing fins and a contaminant disposed on the silicon-containing fins; exposing the substrate to a plasma treatment to remove at least a portion of the contaminant disposed from the silicon-containing fins; then exposing the substrate to an oxidation treatment to produce an oxide layer on the silicon-containing fins and the remaining contaminant thereon; then exposing the substrate to a dry-clean treatment to remove the oxide layer and the remaining contaminant from the silicon-containing fins and produce a cleaned surface thereon; and depositing an epitaxial layer on the cleaned surface on the silicon-containing fins.

2. A method of processing a substrate, comprising: introducing the substrate into a processing system, wherein: the substrate comprises a plurality of silicon-containing fins and a contaminant disposed on the silicon-containing fins; and the processing system comprises a first, second, third, and fourth processing chambers coupled to a mainframe; exposing the substrate to a plasma treatment to remove at least a portion of the contaminant disposed from the silicon-containing fins within the first processing chamber; transferring the substrate from the first processing chamber to the second processing chamber; exposing the substrate to an oxidation treatment to produce an oxide layer on the silicon-containing fins and the remaining contaminant thereon within the second processing chamber; transferring the substrate from the second processing chamber to the third processing chamber; exposing the substrate to a dry-clean treatment to remove the oxide layer and the remaining contaminant from the silicon-containing fins and produce a cleaned surface thereon within the third processing chamber; transferring the substrate from the third processing chamber to the fourth processing chamber; and depositing an epitaxial layer on the cleaned surface on the silicon-containing fins within the fourth processing chamber.

3. A cluster tool for processing a substrate, comprising: a transfer chamber coupled to a load-lock chamber; a first cleaning chamber coupled to the transfer chamber, the first cleaning chamber comprising an inductively coupled plasma source, and the first cleaning chamber is in fluid communication with a source of hydrogen; an oxidation chamber coupled to the transfer chamber, the oxidation chamber comprising a plasma source and is in fluid communication with a source of oxygen; a second cleaning chamber coupled to the transfer chamber, the second cleaning chamber comprising a capacitively coupled plasma source and a substrate support coupling to a bias RF power supply, and the second cleaning chamber is in fluid communication with a source of a fluorine-containing compound; and an epitaxy chamber coupled to the transfer chamber, the epitaxy chamber comprising a liquid precursor vaporizer.

4. The method or the cluster tool according to any one of paragraphs 1-3, wherein the silicon-containing fins comprise silicon-germanium.

5. The method or the cluster tool according to any one of paragraphs 1-4, wherein the plasma treatment comprises exposing the substrate to a hydrogen plasma.

6. The method or the cluster tool according to any one of paragraphs 1-5, wherein the substrate is exposed to the hydrogen plasma for a period of about 0.1 seconds to about 10 minutes.

7. The method or the cluster tool according to any one of paragraphs 1-6, wherein the substrate is exposed to the hydrogen plasma for less than 5 minutes.

8. The method or the cluster tool according to any one of paragraphs 1-7, wherein carbon contained in the contaminant is removed by the hydrogen plasma during the plasma treatment.

9. The method or the cluster tool according to any one of paragraphs 1-8, wherein the oxidation treatment comprises exposing the substrate to an oxidizing agent and to plasma, ions, radicals, or a combination thereof.

10. The method or the cluster tool according to any one of paragraphs 1-9, wherein the oxidizing agent comprises of an oxygen plasma, oxygen, ozone, water, plasmas thereof, ions thereof, radicals thereof, or any combination thereof.

11. The method or the cluster tool according to any one of paragraphs 1-10, wherein the oxidation treatment comprises exposing the substrate to an oxygen plasma generated by a remote plasma source.

12. The method or the cluster tool according to any one of paragraphs 1-11, wherein the substrate is exposed to the oxidizing agent for a period of about 0.1 seconds to about 10 minutes.

13. The method or the cluster tool according to any one of paragraphs 1-12, wherein the substrate is exposed to the oxidizing agent for less than 5 minutes.

14. The method or the cluster tool according to any one of paragraphs 1-13, wherein the oxide layer has a thickness of about 5 Å to about 30 Å.

15. The method or the cluster tool according to any one of paragraphs 1-14, wherein the dry-clean treatment comprises exposing the substrate to an etchant and to plasma, ions, radicals, or a combination thereof.

16. The method or the cluster tool according to any one of paragraphs 1-15, wherein the etchant comprises of fluorine, chlorine, nitrogen, plasmas thereof, ions thereof, radicals thereof, or any combination thereof.

17. The method or the cluster tool according to any one of paragraphs 1-16, wherein the dry-clean treatment comprises exposing the substrate to a fluorine plasma generated from nitrogen trifluoride.

18. The method or the cluster tool according to any one of paragraphs 1-17, wherein the substrate is exposed to the etchant for a period of about 10 seconds to about 20 minutes.

19. The method or the cluster tool according to any one of paragraphs 1-18, wherein the substrate is exposed to the etchant for about 1 minute to about 10 minutes.

20. The method or the cluster tool according to any one of paragraphs 1-19, wherein the epitaxial layer is an epi-silicon layer.

21. The method or the cluster tool according to any one of paragraphs 1-20, wherein the contaminant comprises native oxide, carbon, carbon-containing compounds, organic compounds, siloxanes, mask remnants, or any combination thereof.

22. The method or the cluster tool according to any one of paragraphs 1-21, further comprising: introducing the substrate into a first processing chamber for conducting the plasma treatment; exposing the substrate to the plasma treatment; transferring the substrate from the first processing chamber to a second processing chamber for conducting the oxidation treatment; and exposing the substrate to the oxidation treatment.

23. The method or the cluster tool according to paragraph 22, further comprising: transferring the substrate from the second processing chamber to a third processing chamber for conducting the dry-clean treatment; exposing the substrate to the dry-clean treatment; transferring the substrate from the third processing chamber to a fourth processing chamber for depositing the epitaxial layer; and depositing the epitaxial layer on the cleaned surface.

24. The method or the cluster tool according to paragraph 23, wherein the processing system comprises the first, second, third, and fourth processing chambers coupled to a mainframe.

25. The method or the cluster tool according to paragraph 24, wherein the substrate is transferred between the first, second, third, and fourth processing chambers within a controlled environment maintained by the mainframe.

26. The method or the cluster tool according to paragraph 25, wherein the controlled environment has a lower pressure, a lower oxygen concentration, a lower water concentration, or a combination thereof than the ambient environment outside of the mainframe.

27. The method or the cluster tool according to any one of paragraphs 1-26, wherein the cluster tool further comprises a thermal processing chamber coupled to the transfer chamber.

28. A cluster tool for processing the substrate by the method according to any one of paragraphs 1-27.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising”, it is understood that we also contemplate the same composition or group of elements with transitional phrases “consisting essentially of,” “consisting of”, “selected from the group of consisting of,” or “is” preceding the recitation of the composition, element, or elements and vice versa.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of processing a substrate, comprising:
introducing the substrate into a processing system, wherein the substrate comprises a plurality of silicon-containing fins and a contaminant disposed on the silicon-containing fins;
exposing the substrate to a plasma treatment to remove at least a portion of the contaminant disposed from the silicon-containing fins; then
exposing the substrate to an oxidation treatment to produce an oxide layer on the silicon-containing fins and the remaining contaminant thereon; then
exposing the substrate to a dry-clean treatment to remove the oxide layer and the remaining contaminant from the silicon-containing fins and produce a cleaned surface thereon; and
depositing an epitaxial layer on the cleaned surface on the silicon-containing fins.

2. The method of claim 1, wherein the silicon-containing fins comprise silicon-germanium.

3. The method of claim 1, wherein the plasma treatment comprises exposing the substrate to a hydrogen plasma.

4. The method of claim 3, wherein the substrate is exposed to the hydrogen plasma for a period of about 0.1 seconds to about 10 minutes.

5. The method of claim 3, wherein carbon contained in the contaminant is removed by the hydrogen plasma during the plasma treatment.

6. The method of claim 1, wherein the oxidation treatment comprises exposing the substrate to an oxidizing agent and to plasma, ions, radicals, or a combination thereof.

7. The method of claim 6, wherein the oxidizing agent comprises of an oxygen plasma, oxygen, ozone, water, plasmas thereof, ions thereof, radicals thereof, or any combination thereof.

8. The method of claim 6, wherein the oxidation treatment comprises exposing the substrate to an oxygen plasma generated by a remote plasma source.

9. The method of claim 6, wherein the substrate is exposed to the oxidizing agent for a period of about 0.1 seconds to about 10 minutes.

10. The method of claim 1, wherein the dry-clean treatment comprises exposing the substrate to an etchant and to plasma, ions, radicals, or a combination thereof.

11. The method of claim 10, wherein the etchant comprises of fluorine, chlorine, nitrogen, plasmas thereof, ions thereof, radicals thereof, or any combination thereof.

12. The method of claim 10, wherein the substrate is exposed to the etchant for a period of about 10 seconds to about 20 minutes.

13. The method of claim 1, wherein the epitaxial layer is an epi-silicon layer.

14. The method of claim 1, further comprising:
introducing the substrate into a first processing chamber for conducting the plasma treatment;
exposing the substrate to the plasma treatment;
transferring the substrate from the first processing chamber to a second processing chamber for conducting the oxidation treatment; and
exposing the substrate to the oxidation treatment.

15. The method of claim 14, further comprising:
transferring the substrate from the second processing chamber to a third processing chamber for conducting the dry-clean treatment;
exposing the substrate to the dry-clean treatment;
transferring the substrate from the third processing chamber to a fourth processing chamber for depositing the epitaxial layer; and
depositing the epitaxial layer on the cleaned surface.

16. The method of claim 15, wherein the processing system comprises the first, second, third, and fourth processing chambers coupled to a mainframe.

17. The method of claim 16, wherein the substrate is transferred between the first, second, third, and fourth processing chambers within a controlled environment maintained by the mainframe.

18. The method of claim 17, wherein the controlled environment has a lower pressure, a lower oxygen concentration, a lower water concentration, or a combination thereof than the ambient environment outside of the mainframe.

19. A method of processing a substrate, comprising:
introducing the substrate into a processing system, wherein:
the substrate comprises a plurality of silicon-containing fins and a contaminant disposed on the silicon-containing fins; and
the processing system comprises a first, second, third, and fourth processing chambers coupled to a mainframe;
exposing the substrate to a plasma treatment to remove at least a portion of the contaminant disposed from the silicon-containing fins within the first processing chamber;
transferring the substrate from the first processing chamber to the second processing chamber;
exposing the substrate to an oxidation treatment to produce an oxide layer on the silicon-containing fins and the remaining contaminant thereon within the second processing chamber;
transferring the substrate from the second processing chamber to the third processing chamber;
exposing the substrate to a dry-clean treatment to remove the oxide layer and the remaining contaminant from the silicon-containing fins and produce a cleaned surface thereon within the third processing chamber;
transferring the substrate from the third processing chamber to the fourth processing chamber; and
depositing an epitaxial layer on the cleaned surface on the silicon-containing fins within the fourth processing chamber.

20. A cluster tool for processing a substrate, comprising:
a transfer chamber coupled to a load-lock chamber;
a first cleaning chamber coupled to the transfer chamber, the first cleaning chamber comprising an inductively coupled plasma source, and the first cleaning chamber is in fluid communication with a source of hydrogen;
an oxidation chamber coupled to the transfer chamber, the oxidation chamber comprising a plasma source and is in fluid communication with a source of oxygen;
a second cleaning chamber coupled to the transfer chamber, the second cleaning chamber comprising a capacitively coupled plasma source and a substrate support coupling to a bias RF power supply, and the second cleaning chamber is in fluid communication with a source of a fluorine-containing compound; and
an epitaxy chamber coupled to the transfer chamber, the epitaxy chamber comprising a liquid precursor vaporizer.
